(19) United States
(12) Patent Application Publication
(10) Pub. No.: US 2007/0111427 A1
(43) Pub. Date: May 17, 2007

(54) Semiconductor device and method of manufacturing the same

(76) Inventors: Tomohiro Yamashita, Tokyo (JP); Yukio Nishida, Tokyo (JP); Hidekazu Oda, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/599,382

(22) Filed: Nov. 15, 2006

(30) Foreign Application Priority Data
Nov. 15, 2005 (JP) 2005-329593

(51) Int. Cl. H01L 21/8238

(52) U.S. Cl. 438/231

(57) ABSTRACT

The semiconductor device which can apply the stress application technology to a channel part by a liner film to MISFET including a full silicidation gate electrode, and its manufacturing method are realized. The first liner silicon nitride film is formed on the semiconductor substrate MISFET formed. Insulating films, such as a silicon oxide film, are formed on the first liner silicon nitride film so that it may fully fill up the side of a gate electrode. Next, flattening processing is performed to an insulating film and the first liner silicon nitride film, and a polysilicon gate electrode is exposed. An insulating film is removed leaving the first liner silicon nitride film. The full silicidation of the exposed gate electrode is done, and the second liner silicon nitride film that covers the first liner silicon nitride film and the exposed full silicidation gate electrode is formed.

### CROSS-REFERENCE TO RELATED APPLICATION

The present application claims priority from Japanese patent application No. 2005-329593 filed on Nov. 15, 2005, the content of which is hereby incorporated by reference into this application.

### 1. FIELD OF THE INVENTION

This invention relates to a semiconductor device provided with MISFET (Metal Insulator Semiconductor Field Effect Transistor) including the silicided gate electrode, and its manufacturing method.

### 2. DESCRIPTION OF THE BACKGROUND ART

When the channel part of MISFET is made to generate strain, the mobility of the carrier in an inversion layer will change. Then, the technology of applying physical stress to the channel part of MISFET, generating strain, and improving the driving ability of MISFET is studied.

As one of them, there is a technology described in the following Nonpatent Literature 1. According to this technology, like the description to a Nonpatent Literature 1, the silicon nitride film which covers a substrate front surface, and each MISFET of a P channel type and an N channel type is used as a liner film for stress application. And by applying a compressive stress to P channel type MISFET, and applying a tensile stress to N channel type MISFET, respectively, the driving ability of each MISFET of a P channel type and an N channel type is improved.

As information on prior art documents relevant to invention of this application, there are some as following besides a Nonpatent Literature 1.

[Patent Reference 1] Japanese Unexamined Patent Publication No. 2003-86708

[Patent Reference 2] Japanese Unexamined Patent Publication No. 2005-175121

[Patent Reference 3] Japanese Unexamined Patent Publication No. 2003-273240

[Nonpatent Literature 1] C. D. Sheraw et al., “Dual Stress Liner Enhancement in Hybrid Orientation Technology” 2005 Symposium on VLSI Technology Digest of Technical Papers, pp.12-13

### SUMMARY OF THE INVENTION

Conventionally, the polysilicon in which the impurity ion of the N type or the P type was doped has been adopted as the material of the gate electrode of MISFET. However, when adopting polysilicon as a gate electrode, there are a problem of the increase in effective gate insulating film thickness by depletion-izing of a gate electrode, and a problem of the difficulty of threshold value control at the time of introducing a high dielectric constant gate insulating film. Therefore, in recent years, adoption of the metal gate electrode is studied actively.

The full silicidation (FUSI) gate electrode is proposed as an example of a metal gate electrode. A full silicidation gate electrode is a gate electrode formed by forming metallic films, such as Co and Ni, on the polysilicon gate electrode of MISFET, making polysilicon and a metallic film react and siliciding the whole gate electrode.

When applying the stress application technology to a channel part by a liner film described in the above-mentioned Nonpatent Literature 1 to MISFET including this full silicidation gate electrode, the following problems occur.

A general full silicidation gate electrode formation process has the following steps.

1. Form Structure of a Plurality of MISFET of Having Polysilicon Gate Electrode, on Semiconductor Substrate,

2. By Insulating Films, Such as Silicon Oxide Film, Embed Portion between Polysilicon Gate Electrodes of Each MISFET, and Cover Polysilicon Gate Electrode,

3. After Exposing Front Surface of Polysilicon Gate Electrode, Performing Flattening Processing by CMP (Chemical Mechanical Polishing) Method Etc. to Embedded Insulating Films, Such as Silicon Oxide Film,

4. Deposit Metallic Film on Polysilicon Gate Electrode, and Perform Silicidation Reaction.

On the other hand, with technology described in the above-mentioned Nonpatent Literature 1, forming a liner film so that a gate electrode may be surrounded performs stress application to a channel part. In order to include this stress application technology in the above-mentioned full silicide gate electrode formation process, it is possible to form a liner film before the above-mentioned 2. filling processes of, such as silicon oxide film.

However, when such a policy is taken, even the liner film on a polysilicon gate electrode will be removed in the case of the above-mentioned 3. flattening processing. When the liner film on a polysilicon gate electrode is removed, the stress application effect by a liner film will fade.

This invention was made in view of the above-mentioned situation. The semiconductor device which can apply the stress application technology to the channel part by a liner film to MISFET including a full silicidation gate electrode, and its manufacturing method are offered.

The invention described in claim 1 is a method of manufacturing a semiconductor device, comprising the steps of (a) forming in a semiconductor substrate at least one MISFET (Metal Insulator Semiconductor Field Effect Transistor) which has a silicon gate electrode, a source region, and a drain region; (b) forming a first silicon nitride film which covers the silicon gate electrode, the source region, and the drain region at least over the semiconductor substrate; (c) forming an insulating film over the first silicon nitride film so that the insulating film may fill up a side of the silicon gate electrode; (d) performing flattening processing to the insulating film and the first silicon nitride film, and exposing the silicon gate electrode; (e) removing the insulating film leaving the first silicon nitride film; (f) siliciding the exposed silicon gate electrode; and (g) forming a second silicon nitride film which covers at least the first silicon nitride film, and the exposed silicon gate electrode to which silicidation is finished over the first silicon nitride film and the silicon gate electrode.

The invention described in claim 3 is a semiconductor device, comprising: a semiconductor substrate; a first MISFET (Metal Insulator Semiconductor Field Effect Transistor) which was formed in the semiconductor substrate and which has a silicidation silicon gate electrode, a source region, and a drain region; and a silicon nitride film which covers the source region, the drain region, and a top part of the silicon gate electrode at least; wherein a thickness of the silicon nitride film over the source region and the drain region is larger than a thickness of the silicon nitride film over the top part of the silicon gate electrode.

According to invention according to claim 1, although the first silicon nitride film on a silicon gate electrode is removed by flattening processing, a second silicon nitride film covers a silicon gate electrode again after the silicidation of a silicon gate electrode. Therefore, since the first and the second silicon nitride films near the silicided silicon gate electrode function as a liner film for stress application to a channel part, the manufacturing method of the semiconductor device which can apply the stress application technology to a channel part by a liner film to MISFET including a full silicidation gate electrode is realizable. Since the first silicon nitride film is ending with formation on the source region and the drain region at the time of insulating film formation, when the source region and the drain region are already silicided, an insulating film, and the source region and the drain region do not react.

According to invention according to claim 3, it has a silicon nitride film which covers the source region, a drain region, and the top part of a silicon gate electrode. The thickness of the silicon nitride film on the source region and a drain region is larger than the thickness of the silicon nitride film on the top part of a silicon gate electrode. Since the thickness of the silicon nitride film on the source region and a drain region nearer to a channel part is large, MISFET with high stress application capability to a channel part is obtained. Since the thickness of the silicon nitride film of the top part of a silicon gate electrode is small, thickness of a silicon nitride film with a high dielectric constant can be lessened. Therefore, even if it is a case where metal wiring is formed in the MISFET upper layer, parasitic capacitance between silicon gate electrode-metal wiring can be lessened.

### BRIEF DESCRIPTION OF THE DRAWINGS

FIG. 1 is a cross-sectional view showing the semiconductor device manufactured by the manufacturing method concerning Embodiment 1;

FIGS. 2 to 7 are drawings showing one step of the manufacturing method of the semiconductor device concerning Embodiment 1;

FIGS. 8 to 11 are drawings showing one step of the manufacturing method of the semiconductor device concerning Embodiment 2;

FIG. 12 is a graph which shows the relation of gate voltage-gate capacitance of MISFET which has a full silicidation gate electrode, and MISFET which has a gate electrode which does not perform a silicidation; and

FIG. 13 is a graph which shows the relation between the direction of stress and the amount of stress of a liner silicon nitride film, and the ON-state current of N channel type MISFET and P channel type MISFET.

### DETAILED DESCRIPTION OF THE PREFERRED EMBODIMENTS

### Embodiment 1

This embodiment is the semiconductor device and its manufacturing method which form a second silicon nitride film again on a silicon gate electrode after the full silicidation of a silicon gate electrode, even if the first silicon nitride film on a silicon gate electrode is removed by flattening processing.

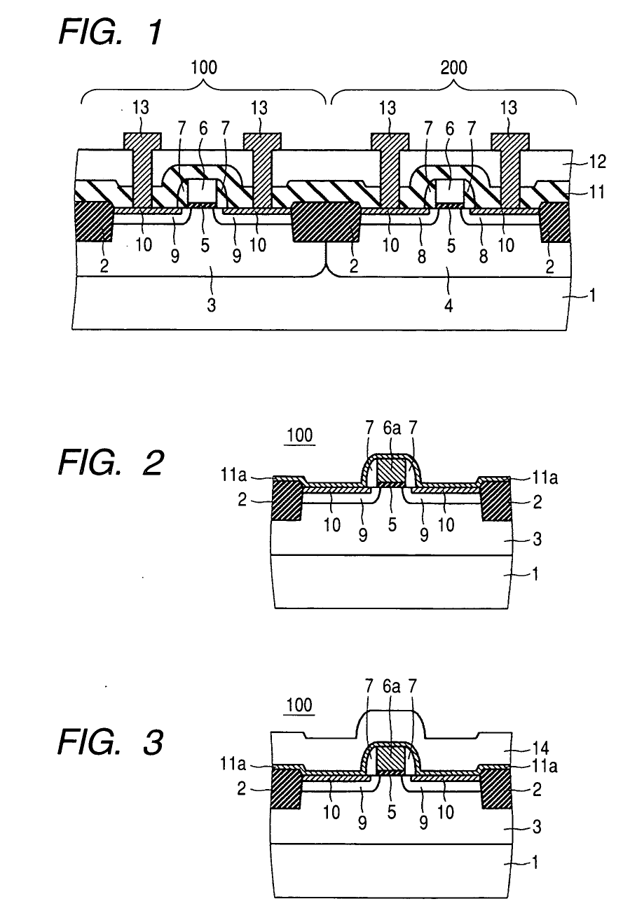

FIG. 1 is a cross-sectional view showing the semiconductor device manufactured by the manufacturing method concerning this embodiment. This semiconductor device has semiconductor substrates 1, such as a silicon substrate, N channel type MISFET 100 and P channel type MISFET 200 which were formed in semiconductor substrate 1, liner silicon nitride film 11, interlayer insulation films 12, such as a silicon oxide film, and a plurality of wirings 13.

In semiconductor substrate 1, P type well 3 into which the P type impurity ion was implanted, and N type well 4 into which the N type impurity ion was implanted are formed. Element isolation films 2, such as a silicon oxide film, are selectively formed in a part of front surface of semiconductor substrate 1.

N channel type MISFET 100 is formed on P type well 3. N channel type MISFET 100 has gate insulating film 5 formed in semiconductor substrate 1 front surface, such as a silicon oxide film, a silicon oxynitride film, and a high dielectric constant insulating film (a hafnium oxide film (HfO₂), a hafnium oxynitride film (HfSiON), etc.), full silicidation silicon gate electrode 6 formed on gate insulating film 5, sidewalls 7 formed in the side surface of gate insulating film 5 and full silicidation silicon gate electrode 6, such as a silicon nitride film, the N type source region and drain region 9 formed in P type well 3, and silicidation region 10 formed in the front surface of the N type source region and drain region 9.

P channel type MISFET 200 is formed on N type well 4. P channel type MISFET 200 has gate insulating film 5 formed in semiconductor substrate 1 front surface, such as a silicon oxide film and a high dielectric constant insulating film (hafnium oxide film etc.), full silicidation silicon gate electrode 6 formed on gate insulating film 5, sidewalls 7 formed in the side surface of gate insulating film 5 and full silicidation silicon gate electrode 6, such as a silicon nitride film, the P type source region and drain region 8 formed in N type well 4, and silicidation region 10 formed in the front surface of the P type source region and drain region 8.

N channel type MISFET 100 and P channel type MISFET 200 are electrically insulated by element isolation film 2. A plurality of wirings 13 are connected to each silicidation region 10 of N channel type MISFET 100 and P channel type MISFET 200 via a contact plug, respectively.

Liner silicon nitride film 11 is a silicon nitride film whose portion is two layer and whose other portions are monolayers, as mentioned later. This liner silicon nitride film 11 bears the stress application function to a channel part as mentioned later.

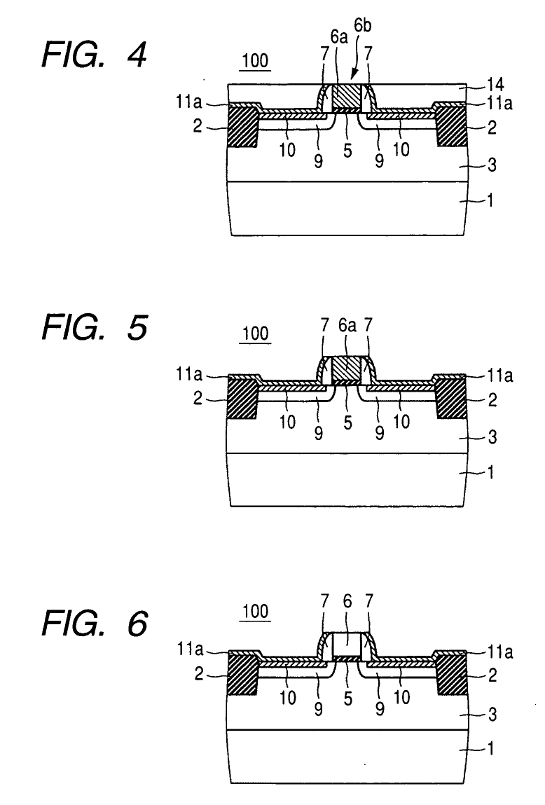

FIG. 2-FIG. 7 are the drawings showing each step of the manufacturing method of the semiconductor device concerning this embodiment. In FIG. 2-FIG. 7, in order to simplify a display, the region of P channel type MISFET 200 is not shown, but only the region of N channel type MISFET 100 is shown. Also in the region of P channel type MISFET 200, each film formation processing, flattening processing, etc. which are mentioned later are performed like the region of N channel type MISFET 100.

First, element isolation films 2, such as a silicon oxide film, are selectively formed in a part of front surface of semiconductor substrate 1 using a thermal oxidation method, trench formation technology, CVD (Chemical Vapor Deposition) technology, etc. Next, impurity ion implantation is performed selectively and P type well 3 is formed in the formation area of N channel type MISFET 100 in semiconductor substrate 1. Impurity ion implantation is performed selectively and N type well 4 is formed in the formation area of P channel type MISFET 200.

Next, N channel type MISFET 100 and P channel type MISFET 200 are formed in semiconductor substrate 1. CVD technology, photolithography technology, and etching technology are used concretely. The laminated structure of gate insulating film 5, such as a silicon oxide film, a silicon oxynitride film, a high dielectric constant insulating film (hafnium oxide film etc.), and polysilicon gate electrode 6a is selectively formed in the front surface of semiconductor substrate 1. Then, impurity ion implantation is performed selectively and the extension regions (not shown) of the P type source region, drain region 8, and the N type source region and a drain region 9 are formed. And film formation of a silicon nitride film etc. and isotropic etching to the silicon nitride film concerned etc. are performed, and sidewall 7 is formed. Then, impurity ion implantation is performed selectively and the P type source region, drain region 8, and the N type source region and a drain region 9 are formed. And silicidation region 10 is formed in each front surface of the P type source region, drain region 8, and the N type source region and a drain region 9.

In this stage, N channel type MISFET 100 and P channel type MISFET 200 do not have full silicidation silicon gate electrode 6, but as shown in FIG. 2, they only have polysilicon gate electrode 6a which is not silicided. Impurity ion, such as B, P, As, In, Sb, F, and N, may be implanted into polysilicon gate electrode 6a.

Next, as shown in FIG. 2, first liner silicon nitride film 11a that covers polysilicon gate electrodes 6a of N channel type MISFET 100 and P channel type MISFET 200, the P type source region, drain region 8, and the N type source region and a drain region 9 at least is formed on semiconductor substrate 1 with CVD technology. Then, as shown in FIG. 3, insulating film 14, such as a silicon oxide film, is formed on first liner silicon nitride film 11a so that it may fully fill up the side of polysilicon gate electrode 6a. This insulating film 14 functions as a film for gate falling prevention in flattening processing of a next step.

Next, as shown in FIG. 4, flattening processing is performed to insulating film 14, and first liner silicon nitride film 11a, and top part 6b of polysilicon gate electrode 6a is exposed. What is necessary is just to adopt the CMP method, or the combination of the CMP method, and the dry or wet etching method as this flattening processing. Then, insulating film 14 is removed, leaving first liner silicon nitride film 11a, as shown in FIG. 5. What is necessary is just to perform wet etching using the etch selectivity of first liner silicon nitride film 11a and insulating films 14, such as a silicon oxide film, in this removing processing.

Next, as shown in FIG. 6, the full silicidation of the exposed polysilicon gate electrode 6a is done, and it is changed in quality to full silicidation silicon gate electrode 6. What is necessary is just to perform heat treatment, a metallic film and polysilicon gate electrode 6a concerned are made to react, and remove the unreacted metallic film concerned, after depositing metallic films (not shown), such as Co, Ni, Pt, Er, and Pd, on polysilicon gate electrode 6a at least in a full silicidation.

In this embodiment, although the full silicidation of the polysilicon gate electrode 6a is done, the present invention does not eliminate the case where not the whole but the portion of polysilicon gate electrode 6a is made to silicide. Therefore, the silicon gate electrode in which the portion is silicided may be adopted instead of full silicidation silicon gate electrode 6.

Next, as shown in FIG. 7, second liner silicon nitride film 11b that covers first liner silicon nitride film 11a and exposed full silicidation silicon gate electrode 6 at least is formed on first liner silicon nitride film 11a and full silicidation silicon gate electrode 6 with plasma-CVD technology etc. The laminated structure of first liner silicon nitride film 11a and second liner silicon nitride film 11b forms liner silicon nitride film 11 of FIG. 1. Namely, liner silicon nitride film 11 is a silicon nitride film of a two layer of first and second liner silicon nitride films 11a and 11b on the P type source region, drain region 8, and the N type source region and a drain region 9. It is a silicon nitride film of the monolayer of only second liner silicon nitride film 11b on full silicidation silicon gate electrode 6.

Then, interlayer insulation film 12 is formed on liner silicon nitride film 11, and a contact hole is formed with photolithography technology and etching technology in interlayer insulation film 12 and liner silicon nitride film 11. And when forming a metallic film (not shown) in the inside of a contact hole, and interlayer insulation film 12 front surface and forming wiring 13 by the damascene method etc;, the structure of FIG. 1 will be acquired.

According to the manufacturing method of the semiconductor device concerning this embodiment, first liner silicon nitride film 11a on polysilicon gate electrode 6a is removed by flattening processing, but second liner silicon nitride film 11b covers full silicidation silicon gate electrode 6 again after the silicidation of polysilicon gate electrode 6a. Therefore, since first and second liner silicon nitride films 11a and 11b of the full silicidation silicon gate electrode 6 neighborhood function as a liner film for stress application to a channel part, the manufacturing method of the semiconductor device which can apply the stress application technology to the channel part by a liner film to MISFET including full silicidation silicon gate electrode 6 is realizable. Since first liner silicon nitride film 11a is ending with formation on the P type and N type source region and drain region 8 and 9 at the time of formation of insulating film 14, when the P type and N type source region and drain region 8 and 9 are already silicided (silicidation region 10 is included), insulating film 14, and the P type and N type source region and drain region 8 and 9 do not react.

In the structure of the semiconductor device concerning this embodiment, liner silicon nitride film 11 covers the P type and N type source region, drain region 8 and 9, and the top part of full silicidation silicon gate electrode 6 at least. And as shown in FIG. 7, thickness t1 of the laminated film of the first and the second liner silicon nitride films 11a and 11b on the P type and N type source region and drain region 8 and 9 is larger than thickness t2 of second liner silicon nitride film 11b on the top part of full silicidation gate electrode 6.

That is, according to the semiconductor device concerning this embodiment, thickness t1 of liner silicon nitride film 11 on the P type and N type source region and drain region 8 and 9 is larger than thickness t2 of liner silicon nitride film 11 on the top part of full silicidation silicon gate electrode 6. Since the thickness of liner silicon nitride film 11 on the P type and N type source region and drain region 8 and 9 nearer to a channel part is large, MISFET with high stress application capability to a channel part is obtained. Since the thickness of liner silicon nitride film 11 of the top part of full silicidation silicon gate electrode 6 is small, thickness of liner silicon nitride film 11 with a high dielectric constant can be lessened. Therefore, even if it is a case where metal wiring 13 is formed in the MISFET upper layer, parasitic capacitance between full silicidation silicon gate electrode 6-metal wiring 13 can be lessened.

Liner silicon nitride film 11 includes first liner silicon nitride film 11a which at least covers the P type and N type source region and drain region 8 and 9, and which does not cover the top part of full silicidation silicon gate electrode 6, and second liner silicon nitride film 11b which covers first liner silicon nitride film 11a and the top part of full silicidation silicon gate electrode 6 at least. Therefore, P type and N type source region and drain region 8 and 9 upper part constitutes a laminated film of the first and the second liner silicon nitride films 11a and 11b. In the top part of full silicidation silicon gate electrode 6, first liner silicon nitride film 11a does not exist, but it has become a single layer film of second liner silicon nitride film 11b. Therefore, the structure of liner silicon nitride film 11 where thickness t1 is larger than thickness t2 can be acquired easily.

### Embodiment 2

This embodiment is a modification of the semiconductor device and its manufacturing method concerning Embodiment 1. After performing the step to FIG. 7, second liner silicon nitride film 11b near P channel type MISFET 200 is removed leaving second liner silicon nitride film 11b near N channel type MISFET 100, and third liner silicon nitride film 11c is formed in P channel type MISFET 200 side.

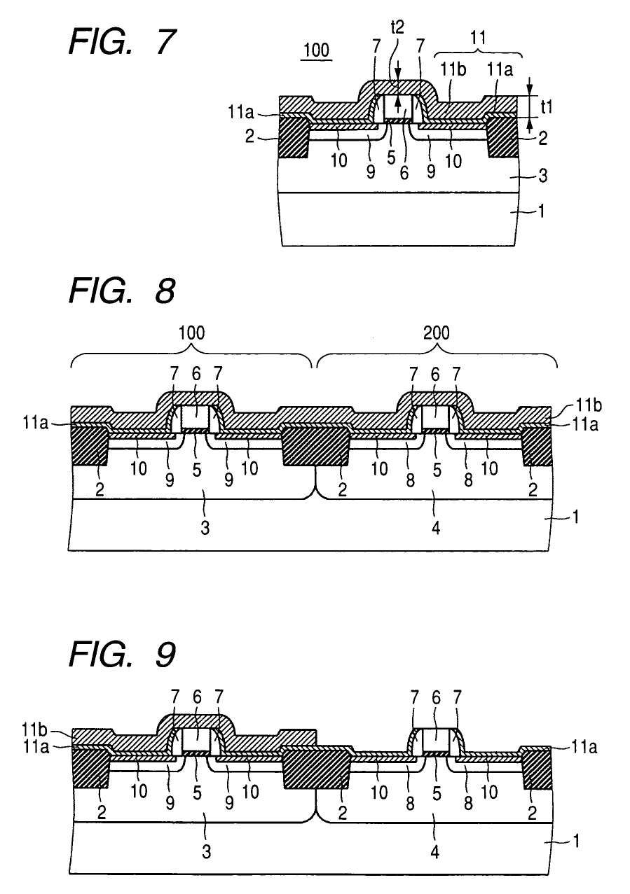

FIG. 8-FIG. 11 are the drawings showing each step of a manufacturing method of a semiconductor device concerning this embodiment. First, the steps of FIG. 2-FIG. 7 described in Embodiment 1 are performed to the both sides of N channel type MISFET 100 and P channel type MISFET 200. The structure of a semiconductor device where first liner silicon nitride film 11a and second liner silicon nitride film 11b were formed by this in both the regions of N channel type MISFET 100 and P channel type MISFET 200 shown in FIG. 8 is acquired.

Next, as shown in FIG. 9, second liner silicon nitride film 11b near P channel type MISFET 200 is removed, leaving second liner silicon nitride film 11b near N channel type MISFET 100. What is necessary is just to pattern second liner silicon nitride film 11b with photolithography technology and etching technology in this removing processing.

Next, third liner silicon nitride film 11c that covers first liner silicon nitride film 11a on P channel type MISFET 200, and full silicidation silicon gate electrode 6 of P channel type MISFET 200 at least as shown in FIG. 10 is formed with plasma-CVD technology etc. on first liner silicon nitride film 11a and full silicidation silicon gate electrode 6 of P channel type MISFET 200, and second liner silicon nitride film 11b of N channel type MISFET 100.

In formation of this third liner silicon nitride film 11c, what is necessary is just to adopt a different value of the plasma power and the gas flow rate of a plasma CVD device from the plasma power and the gas flow rate of a plasma CVD device at the time of second liner silicon nitride film 11b formation. Thus, by controlling the various process conditions at the time of film formation of the second and the third liner silicon nitride films 11b and 11c, third liner silicon nitride film 11c can be used as a compressive liner film, and second liner silicon nitride film 11b can be used as a tensile liner film. When tensile stress application of the liner film on N channel type MISFET 100 is enabled, and compressive stress application of the liner film on P channel type MISFET 200 is possible, driving ability improves in the both sides of N and P channel type MISFET 100, 200.

And as shown in FIG. 11, third liner silicon nitride film 11c of the N channel type MISFET 100 neighborhood is removed, leaving third liner silicon nitride film 11c of the P channel type MISFET 200 neighborhood. What is necessary is just to pattern third liner silicon nitride film 11c with photolithography technology and etching technology in this removing processing.

Thus, according to the manufacturing method of the semiconductor device concerning this embodiment, on first liner silicon nitride film 11a on P channel type MISFET 200, and full silicidation silicon gate electrode 6 of P channel type MISFET 200, third liner silicon nitride film 11c is formed instead of second liner silicon nitride film 11b. Therefore, by forming the second and the third liner silicon nitride films 11b and 11c on different process conditions, one side of the second and the third liner silicon nitride films 11b and 11c can be used as a compressive liner film, and another side can be used as a tensile liner film.

In the structure of the semiconductor device concerning this embodiment, first liner silicon nitride film 11a on P channel type MISFET 200 can be grasped as the third liner silicon nitride film which covers the P type source region and drain region 8 at least, and which does not cover the top part of full silicidation silicon gate electrode 6 of P channel type MISFET 200, and liner silicon nitride film 11c on P channel type MISFET 200 can be grasped as the fourth liner silicon nitride film which covers third liner silicon nitride film 11a and the top part of full silicidation gate electrode 6 of P channel type MISFET 200 at least. And it can be said in this case that fourth liner silicon nitride film 11c on P channel type MISFET 200 is a compressive liner film, and second liner silicon nitride film 11b on N channel type MISFET 100 is a tensile liner film.

Therefore, according to the semiconductor device concerning this embodiment, since one side of the second and the fourth liner silicon nitride films 11b and 11c is a compressive liner film and another side is a tensile liner film, a compressive stress can be applied to one side of N channel type and P channel type MISFET 100,200, a tensile stress can be applied to another side, and the driving ability of each MISFET 100,200 of an N channel type and a P channel type can be improved.

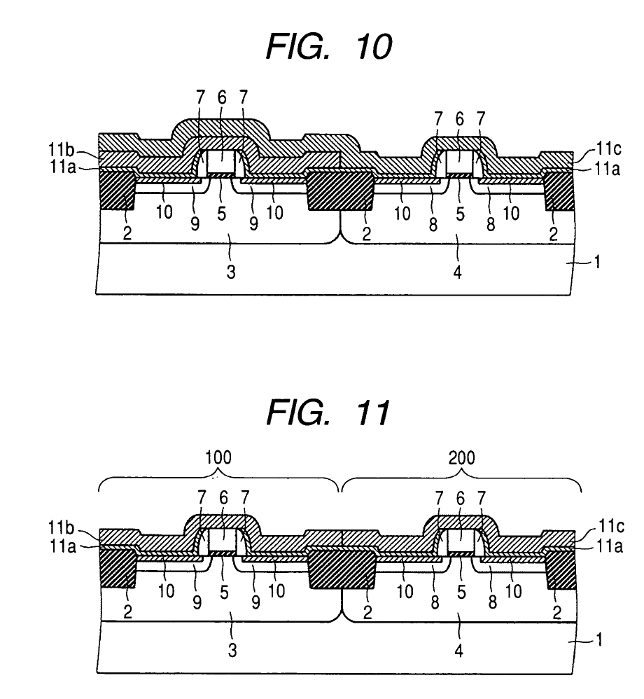

FIG. 12 is a graph which shows the relation of gate voltage-gate capacitance of MISFET which has a full silicidation gate electrode, and MISFET which has a polysilicon gate electrode which does not perform a silicidation. In the side of a full silicidation gate electrode, gate capacitance will increase, effectual gate insulating film thickness will reduce thickness, and the driving ability of MISFET will improve as FIG. 12 shows. This is considered to originate in gate depletion-ization seen with a polysilicon gate electrode being suppressed with a full silicidation gate electrode. In any case of an N channel type and a P channel type, it becomes the graph characteristics of FIG. 12.

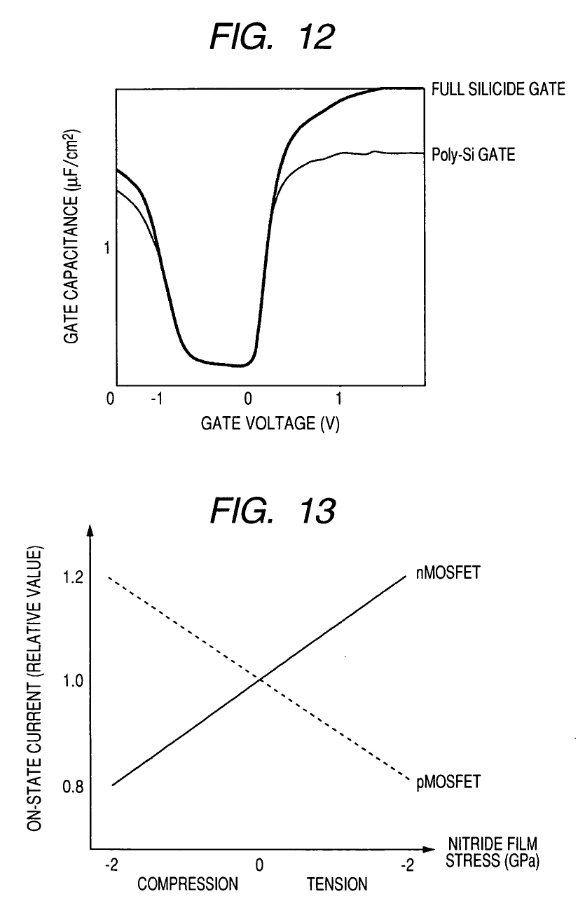

FIG. 13 is a graph which indicates relations between the direction of stress and the amount of stress of a liner silicon nitride film and the ON-state current of N channel type MISFET and P channel type MISFET. When adopting a tensile liner silicon nitride film as shown in FIG. 13, the ON-state current of N channel type MISFET will increase, and the driving ability will improve. When adopting a compressive liner silicon nitride film, the ON-state current of P channel type MISFET will increase, and the driving ability will improve.

Therefore, liner silicon nitride film 11c at the side of P channel type MISFET 200 can be used as a compressive liner film, liner silicon nitride film 11b at the side of N channel type MISFET 100 can be used as a tensile liner film, and the driving ability of both MISFET's can be improved.

What is necessary is just to adopt a silicon nitride film with few amounts of stress about liner silicon nitride film 11a which exists on both MISFET. Then, driving ability of one side of N-channel type MISFET 100 and P channel type MISFET 200 is not heightened superfluously, and driving ability of another side is not reduced.

What is claimed is:

1. A method of manufacturing a semiconductor device, comprising the steps of
(a) forming in a semiconductor substrate at least one MISFET (Metal Insulator Semiconductor Field Effect Transistor) which has a silicon gate electrode, a source region, and a drain region;
(b) forming a first silicon nitride which covers at least the silicon gate electrode, the source region, and the drain region film over the semiconductor substrate;
(c) forming an insulating film over the first silicon nitride film so that the insulating film may fill up a side of the silicon gate electrode;
(d) performing flattening processing to the insulating film and the first silicon nitride film, and exposing the silicon gate electrode;
(e) removing the insulating film leaving the first silicon nitride film;
(f) siliciding the exposed silicon gate electrode; and
(g) forming a second silicon nitride film which covers at least the first silicon nitride film, and the exposed silicon gate electrode to which silicidation is finished.

2. A method of manufacturing a semiconductor device according to claim 1, wherein
first MISFET of a first conductivity type; and second MISFET of a second conductivity type different from the first conductivity type are included in the at least one MISFET; and
the step (a) through (g) are performed to both sides of the first and the second MISFET; further comprising the steps of:
(h) removing the second silicon nitride film near the second MISFET leaving the second silicon nitride film near the first MISFET after the step (g); and
(i) forming a third silicon nitride film which covers the first silicon nitride film over the second MISFET, and the silicon gate electrode of the second MISFET.

3. A semiconductor device, comprising:
a semiconductor substrate;
a first MISFET (Metal Insulator Semiconductor Field Effect Transistor) which was formed in the semiconductor substrate and which has a silicidation silicon gate electrode, a source region, and a drain region; and
a silicon nitride film which covers the source region, the drain region, and a top part of the silicon gate electrode at least;
wherein a thickness of the silicon nitride film over the source region and the drain region is larger than a thickness of the silicon nitride film over the top part of the silicon gate electrode.

4. A semiconductor device according to claim 3, wherein
the silicon nitride film comprises:
a first silicon nitride film which covers the source region and the drain region at least, and does not cover a top part of the silicon gate electrode; and
a second silicon nitride film which covers the first silicon nitride film, and the top part of the silicon gate electrode at least.

5. A semiconductor device according to claim 4, further comprising:
a second MISFET of a different conductivity type from the first MISFET which was formed in the semiconductor substrate and which has a silicidation silicon gate electrode, a source region, and a drain region;
a third silicon nitride film which covers the source region and the drain region of the second MISFET at least, and does not cover a top part of the silicon gate electrode of the second MISFET; and
a fourth silicon nitride film which covers the third silicon nitride film, and the top part of the silicon gate electrode of the second MISFET at least;
wherein one side of the second and the fourth silicon nitride films is a compressive liner film, and another side is a tensile liner film.
